(19) United States
(12) Patent Application Publication
(10) Pub. No.: US 2023/0137468 A1
(43) Pub. Date: May 4, 2023

(54) DIELECTRIC COATED TRANSVERSELY-EXCITED FILM BULK ACOUSTIC RESONATOR (XBAR) FOR COUPLING OPTIMIZATION

(71) Applicant: Murata Manufacturing Co., Ltd., Nagaokakyo-shi (JP)

(72) Inventor: Bryant Garcia, Mississauga (CA)

(21) Appl. No.: 17/940,881

(22) Filed: Sep. 8, 2022

Related U.S. Application Data
(60) Provisional application No. 63/275,872, filed on Nov. 4, 2021.

(51) Int. Cl. H03H 9/02; H03H 9/17; H03H 3/02; H03H 9/56

(52) U.S. Cl. CPC H03H 9/02228; H03H 3/02; H03H 9/174; H03H 9/568; H03H 9/02157; H03H 2003/023

(57) ABSTRACT

An acoustic resonator has a piezoelectric plate, a portion of the piezoelectric plate spanning a cavity in an intermediate layer of a substrate. The resonator also has an interdigital transducer on a surface of the piezoelectric plate, interleaved fingers of the IDT on the portion of the piezoelectric plate that spans the cavity The resonator has a dielectric layer over the interleaved fingers and the surface of the portion of the piezoelectric plate that spans the cavity. A thickness of the dielectric layer optimizes electromechanical coupling of the acoustic resonator.

A portion of the disclosure of this patent document contains material which is subject to copyright protection. This patent document may show and/or describe matter which is or may become trade dress of the owner. The copyright and trade dress owner has no objection to the facsimile reproduction by anyone of the patent disclosure as it appears in the Patent and Trademark Office patent files or records, but otherwise reserves all copyright and trade dress rights whatsoever.

### RELATED APPLICATION INFORMATION

This patent claim priority to co-pending provisional patent application no. 63/275,872, filed Nov. 04, 2021, entitled DIELECTRIC COATED XBAR FOR COUPLING OPTIMIZATION, which is incorporated herein by reference.

### BACKGROUND

### Field

This disclosure relates to radio frequency filters using acoustic wave resonators, and specifically to filters for use in communications equipment.

### Description of the Related Art

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “pass-band” of the filter. The range of frequencies stopped by such a filter is referred to as the “stop-band” of the filter. A typical RF filter has at least one pass-band and at least one stop-band. Specific requirements on a passband or stop-band depend on the specific application. For example, a “pass-band” may be defined as a frequency range where the insertion loss of a filter is better than a defined value such as 1 dB, 2 dB, or 3 dB. A “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front-ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

RF filters typically require many design trade-offs to achieve, for each specific application, the best compromise between performance parameters such as insertion loss, rejection, isolation, power handling, linearity, size and cost. Specific design and manufacturing methods and enhancements can benefit simultaneously one or several of these requirements.

Performance enhancements to the RF filters in a wireless system can have broad impact to system performance. Improvements in RF filters can be leveraged to provide system performance improvements such as larger cell size, longer battery life, higher data rates, greater network capacity, lower cost, enhanced security, higher reliability, etc. These improvements can be realized at many levels of the wireless system both separately and in combination, for example at the RF module, RF transceiver, mobile or fixed sub-system, or network levels.

High performance RF filters for present communication systems commonly incorporate acoustic wave resonators including surface acoustic wave (SAW) resonators, bulk acoustic wave (BAW) resonators, film bulk acoustic wave resonators (FBAR), and other types of acoustic resonators. However, these existing technologies are not well-suited for use at the higher frequencies and bandwidths proposed for future communications networks.

The desire for wider communication channel bandwidths will inevitably lead to the use of higher frequency communications bands. Radio access technology for mobile telephone networks has been standardized by the 3GPP (3^{rd} Generation Partnership Project). Radio access technology for 5^{th} generation mobile networks is defined in the 5G NR (new radio) standard. The 5G NR standard defines several new communications bands. Two of these new communications bands are n77, which uses the frequency range from 1300 MHz to 4200 MHz, and n79, which uses the frequency range from 4400 MHz to 5000 MHz. Both band n77 and band n79 use time-division duplexing (TDD), such that a communications device operating in band n77 and/or band n79 use the same frequencies for both uplink and downlink transmissions. Bandpass filters for bands n77 and n79 must be capable of handling the transmit power of the communications device. WiFi bands at 5 GHz and 6 GHz also require high frequency and wide bandwidth. The 5G NR standard also defines millimeter wave communication bands with frequencies between 24.25 GHz and 40 GHz.

The Transversely-Excited Film Bulk Acoustic Resonator (XBAR) is an acoustic resonator structure for use in microwave filters. The XBAR is described in patent US 10,491,291, titled TRANSVERSELY EXCITED FILM BULK ACOUSTIC RESONATOR. An XBAR resonator comprises an interdigital transducer (IDT) formed on a thin floating layer, or diaphragm, of a single-crystal piezoelectric material. The IDT includes a first set of parallel fingers, extending from a first busbar and a second set of parallel fingers extending from a second busbar. The first and second sets of parallel fingers are interleaved. A microwave signal applied to the IDT excites a shear primary acoustic wave in the piezoelectric diaphragm. XBAR resonators provide very high electromechanical coupling and high frequency capability. XBAR resonators may be used in a variety of RF filters including band-reject filters, band-pass filters, duplexers, and multiplexers. XBARs are well suited for use in filters for communications bands with frequencies above 3 GHz.

### DESCRIPTION OF THE DRAWINGS

FIG. 1 includes a schematic plan view and two schematic cross-sectional views of a transversely-excited film bulk acoustic resonator (XBAR).

FIG. 2 is an expanded schematic cross-sectional view of a portion of the XBAR of FIG. 1.

FIG. 3A is an alternative schematic cross-sectional view of an XBAR.

FIG. 3B is a graphical illustration of the primary acoustic mode of interest in an XBAR.

FIG. 4 shows a graph of the coupling of an XBAR as a function of frontside oxide thickness/plate thickness.

FIG. 5 shows a graph of the coupling of two XBARs as a function of each of their frontside dielectric thickness/plate thickness.

FIG. 6 is a flow chart of a conventional process for fabricating an XBAR.

Throughout this description, elements appearing in figures are assigned three-digit or four-digit reference designators, where the two least significant digits are specific to the element and the one or two most significant digit is the figure number where the element is first introduced. An element that is not described in conjunction with a figure may be presumed to have the same characteristics and function as a previously-described element having the same reference designator or the same two least significant digits.

### DETAILED DESCRIPTION

### Description of Apparatus

The Transversely-Excited Film Bulk Acoustic Resonator (XBAR) is a new resonator structure for use in microwave filters. The XBAR is described in patent US 10,491,291, titled TRANSVERSELY EXCITED FILM BULK ACOUSTIC RESONATOR, which is incorporated herein by reference in its entirety. An XBAR resonator comprises a conductor pattern having an interdigital transducer (IDT) formed on a thin floating layer or diaphragm of a piezoelectric material. The IDT has two busbars which are each attached to a set of fingers and the two sets of fingers are interleaved on the diaphragm over a cavity formed in a substrate upon which the resonator is mounted. The diaphragm spans the cavity and may include front-side and/or back-side dielectric layers. A microwave signal applied to the IDT excites a shear primary acoustic wave in the piezoelectric diaphragm, such that the acoustic energy flows substantially normal to the surfaces of the layer, which is orthogonal or transverse to the direction of the electric field generated by the IDT. XBAR resonators provide very high electromechanical coupling and high frequency capability.

A piezoelectric membrane may be a part of a plate of single-crystal piezoelectric material that spans a cavity in the substrate. A piezoelectric diaphragm may be the membrane and may include the front-side and/or back-side dielectric layers. An XBAR resonator may be such a diaphragm or membrane with an interdigital transducer (IDT) formed on the diaphragm or membrane. Contact pads can be formed at selected locations over the surface of the substrate to provide electrical connections between the IDT and contact bumps to be attached to or formed on the contact pads.

Passband filter bands at 5G frequencies are often wide bandwidth. The ability to realize a given bandwidth with a ladder filter configuration can be directly proportional to the resonator bandwidth of resonators in the filter configuration. Therefore, it is often beneficial to maximize the resonator coupling. The filter band edges are typically defined by the sharp resonance or anti-resonance features of the shunt and series resonator structures. If the coupling of the resonators is insufficient, it is not possible to provide an adequate match (e.g., of shunt and series resonator resonance or anti-resonance frequencies) over the filter bandwidth and the return loss suffers. In some cases, the wider the difference between resonance and anti-resonance of the resonators, the wider the desired passband bandwidth. In a prototypical XBAR ladder filter, the shunt resonance frequency sits at the lower band edge, the series anti-resonance frequency sits at the upper band edge, and the shunt anti-resonance and series resonance align in the center of the band. This provides a relatively constant impedance across the filter band, which can be simply matched to. To the extent that the resonance/anti-resonance features (e.g., of the shunt and series resonators, respectively) are separated, the impedance in that region suffers and one typically sees a ‘sag’ in the response as the return loss grows.

The following describes improved XBAR resonators, filters and fabrication techniques for dielectric coated XBARs for coupling optimization to increase energy coupling between the IDT fingers and the piezoelectric plate for wider resonator bandwidth. The word coupling may have many meanings. In this context, the coupling is the frequency separation between resonance and anti-resonance for a resonator. This is directly proportional to the “electromechanical coupling”, which is the ratio of mechanical energy (e.g., energy put into the resonator A1 mode for an A1 mode resonator) versus electrical input energy. In this sense, it is how well the input electrical energy “couples” into the mechanical A1 XBAR mode trying to be excited.

The coupling of an XBAR is dependent on numerous factors including the piezoelectric material and cut angle. The coupling may be increased by providing a frontside dielectric coating of appropriate thickness over the surface of the piezoelectric plate and IDT or fingers. By tuning the front side dielectric coating thickness, the coupling can be maximized when the ratio of dielectric coating (e.g., an oxide such as silicon oxide) thickness to piezoelectric plate thickness is approximately or at 20%.

In some cases, an acoustic resonator has a piezoelectric plate, a portion of the piezoelectric plate spanning a cavity in a substrate. The resonator also has an interdigital transducer on a surface of the piezoelectric plate, interleaved fingers of the IDT on the portion of the piezoelectric plate that spans the cavity The resonator has a dielectric layer over the interleaved fingers and the surface of the portion of the piezoelectric plate that spans the cavity. A thickness of the dielectric layer is selected to optimize electromechanical coupling of the acoustic resonator.

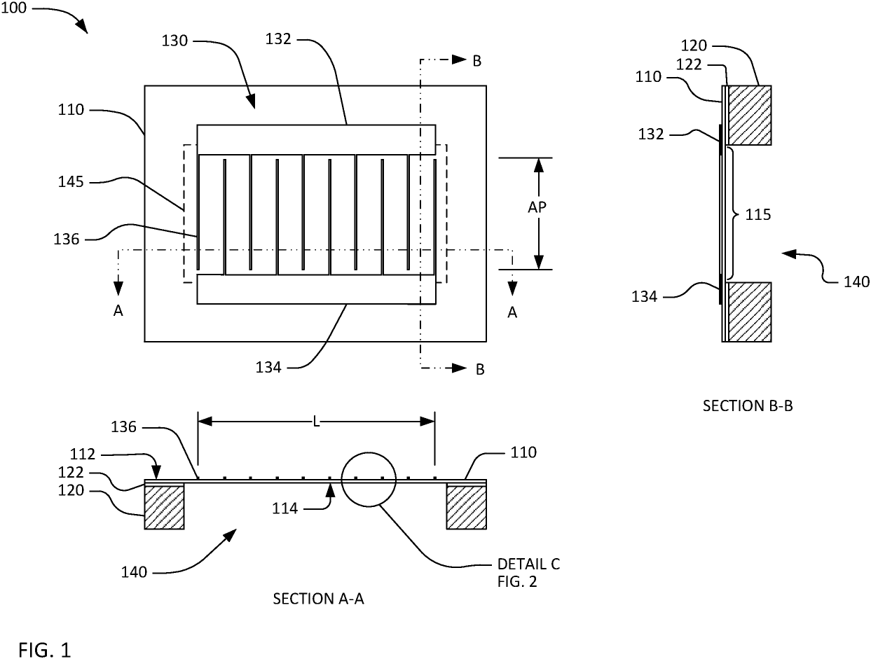

FIG. 1 shows a simplified schematic top view and orthogonal cross-sectional views of a transversely-excited film bulk acoustic resonator (XBAR) 100. XBAR resonators such as the resonator 100 may be used in a variety of RF filters including band-reject filters, band-pass filters, duplexers, and multiplexers. XBARs are particularly suited for use in filters for communications bands with frequencies above 3 GHz.

The XBAR 100 is made up of a thin film conductor pattern formed on a surface of a piezoelectric plate 110 having parallel front and back surfaces 112, 114, respectively. The piezoelectric plate is a thin single-crystal layer of a piezoelectric material such as lithium niobate, lithium tantalate, lanthanum gallium silicate, gallium nitride, or aluminum nitride. The piezoelectric plate is cut such that the orientation of the X, Y, and Z crystalline axes with respect to the front and back surfaces is known and consistent. The piezoelectric plate may be Z-cut (which is to say the Z axis is normal to the front and back surfaces 112, 114), rotated Z-cut, or rotated YX cut. XBARs may be fabricated on piezoelectric plates with other crystallographic orientations.

The back surface 114 of the piezoelectric plate 110 is attached to a substrate 120 that provides mechanical support to the piezoelectric plate 110. The substrate 120 may be, for example, silicon, sapphire, quartz, or some other material. The substrate may have layers of silicon thermal oxide (TOX) and crystalline silicon. The back surface 114 of the piezoelectric plate 110 may be bonded to the substrate 120 using a wafer bonding process, or grown on the substrate 120, or attached to the substrate in some other manner. The piezoelectric plate is attached directly to the substrate or may be attached to the substrate via a bonding oxide (BOX) layer or an intermediate layer 122, such as a layer of SiO2, or another oxide such as A12O3.

As shown in FIG. 1, the diaphragm 115 is contiguous with the rest of the piezoelectric plate 110 around all of a perimeter 145 of the cavity 1. In this context, “contiguous” means “continuously connected without any intervening item”. However, it is possible for a bonding oxide layer (BOX) to bond the plate 110 to the substrate 120. The BOX layer may exist between the plate and substrate around perimeter 145 and may extend further away from the cavity than just within the perimeter itself. In the absence of a process to remove it (i.e., this invention) the BOX is everywhere between the piezoelectric plate and the substrate. The BOX is typically removed from the back of the diaphragm 115 as part of forming the cavity.

The conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved. The interleaved fingers 136 overlap for a distance AP, commonly referred to as the “aperture” of the IDT. The center-to-center distance L between the outermost fingers of the IDT 130 is the “length” of the IDT.

The first and second busbars 132, 134 serve as the terminals or electrodes of the XBAR 100. A radio frequency or microwave signal applied between the two busbars 132, 134 of the IDT 130 excites a primary acoustic mode within the piezoelectric plate 110. As will be discussed in further detail, the excited primary acoustic mode is a bulk shear mode where acoustic energy propagates along a direction substantially orthogonal to the surface of the piezoelectric plate 110, which is also normal, or transverse, to the direction of the electric field created by the IDT fingers. Thus, the XBAR is considered a transversely-excited film bulk wave resonator.

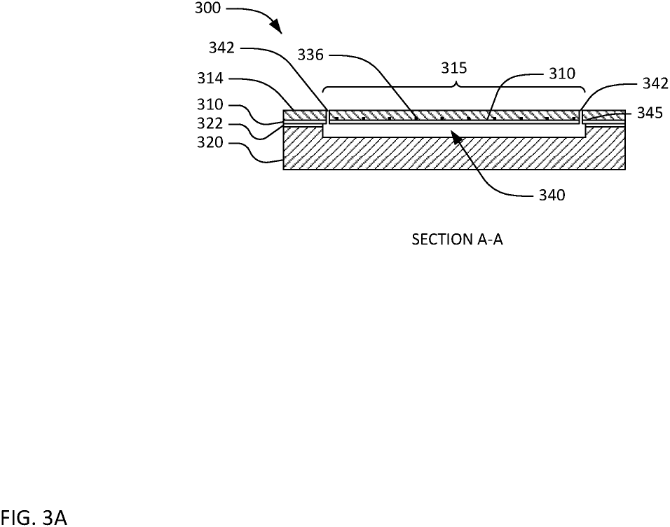

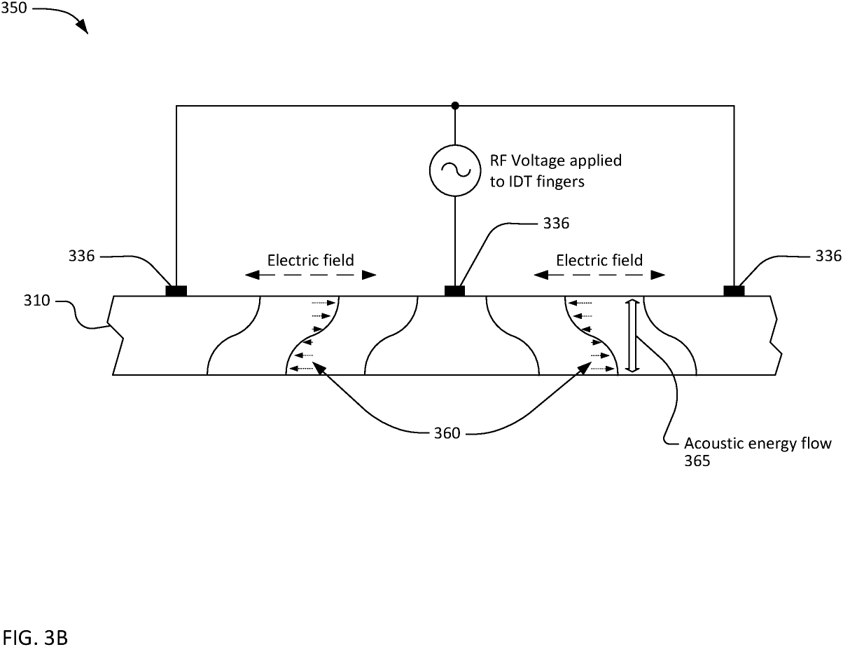

A cavity 140 is formed in the substrate 120 such that a portion 115 of the piezoelectric plate 110 containing the IDT 130 is suspended over the cavity 140 without contacting the substrate 120 or the bottom of the cavity. “Cavity” has its conventional meaning of “an empty space within a solid body.” The cavity may contain a gas, air, or a vacuum. In some case, there is also a second substrate, package or other material having a cavity (not shown) above the plate 110, which may be a mirror image of substrate 120 and cavity 140. The cavity above plate 110 may have an empty space depth greater than that of cavity 140. The fingers extend over (and part of the busbars may optionally extend over) the cavity (or between the cavities). The cavity 140 may be a hole completely through the substrate 120 (as shown in Section A-A and Section B-B of FIG. 1) or a recess in the substrate 120 (as shown subsequently in FIG. 3A). The cavity 140 may be formed, for example, by selective etching of the substrate 120 before or after the piezoelectric plate 110 and the substrate 120 are attached. As shown in FIG. 1, the cavity 140 has a rectangular shape with an extent greater than the aperture AP and length L of the IDT 130. A cavity of an XBAR may have a different shape, such as a regular or irregular polygon. The cavity of an XBAR may more or fewer than four sides, which may be straight or curved.

The portion 115 of the piezoelectric plate suspended over the cavity 140 will be referred to herein as the “diaphragm” (for lack of a better term) due to its physical resemblance to the diaphragm of a microphone. The diaphragm may be continuously and seamlessly connected to the rest of the piezoelectric plate 110 around all, or nearly all, of perimeter of the cavity 140. In this context, “contiguous” means “continuously connected without any intervening item”. In some cases, a BOX layer may bond the plate 110 to the substrate 120 around the perimeter.

For ease of presentation in FIG. 1, the geometric pitch and width of the IDT fingers is greatly exaggerated with respect to the length (dimension L) and aperture (dimension AP) of the XBAR. A typical XBAR has more than ten parallel fingers in the IDT 110. An XBAR may have hundreds, possibly thousands, of parallel fingers in the IDT 110. Similarly, the thickness of the fingers in the cross-sectional views is greatly exaggerated.

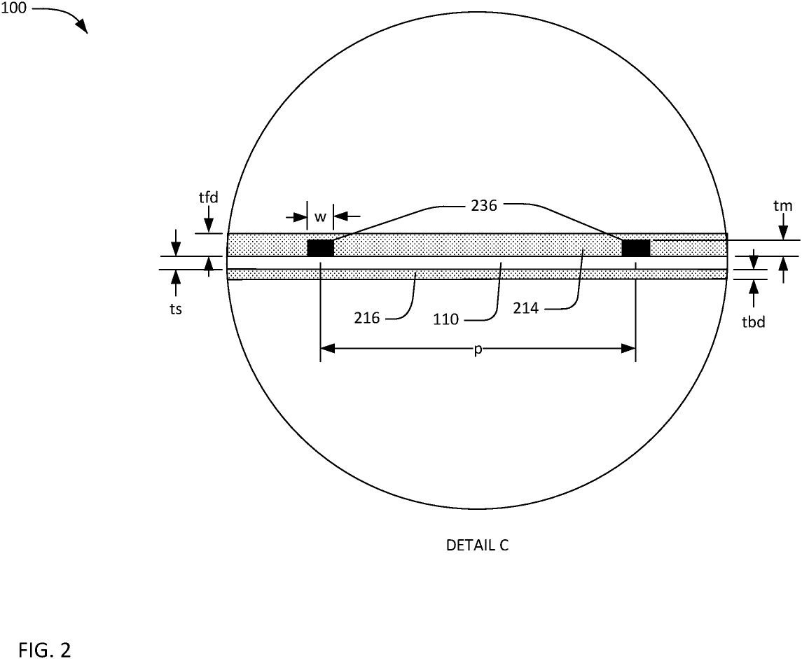

FIG. 2 shows a detailed schematic cross-sectional view of the XBAR 100 of FIG. 1. The cross-sectional view may be a portion of the XBAR 100 that includes fingers of the IDT. The piezoelectric plate 110 is a single-crystal layer of piezoelectrical material having a thickness ts. The ts may be, for example, 100 nm to 1500 nm. When used in filters for LTE™ bands from 3.4 GHZ to 6 GHz (e.g., bands 42, 43, 46), the thickness ts may be, for example, 200 nm to 1000 nm.

The plate 110 may be Z-cut LN or 128-Y Cut LN with a thickness ts of between 300 nm and 500 nm. It may have a thickness ts of between 350 nm and 450 nm. The thickness ts may be 400 nm.

A front-side dielectric layer 214 is formed on the front side of the piezoelectric plate 110. The “front side” of the XBAR is, by definition, the surface facing away from the substrate. The front-side dielectric layer 214 has a thickness tfd. The front-side dielectric layer 214 is formed between and over the IDT fingers 236.

The front side dielectric layer 214 is deposited over the plate 110 and over the IDT fingers 236; and then may be polished or planarized. In some cases, the deposition forms a blanket layer or conformal layer, such as by ALD, PVD, PECVD, CVD or another dielectric layer deposition process. The layer may then be planarized such as by chemical mechanical polishing (CMP) or another known dielectric planarizing process.

A back-side dielectric layer 216 may optionally be formed on the back side of the piezoelectric plate 110. The back-side dielectric layer may be or include the BOX layer. The back-side dielectric layer 216 has a thickness tbd. The front-side and back-side dielectric layers 214, 216 may be a non-piezoelectric dielectric material, such as an oxide, a silicon oxide, silicon dioxide, silicon nitride, aluminum oxide and/or another dielectric material. The tfd and tbd may each be, for example, 0 to 500 nm. tfd and tbd are typically less than the thickness ts of the piezoelectric plate. The tfd and tbd are not necessarily equal, and the front-side and back-side dielectric layers 214, 216 are not necessarily the same material. Either or both of the front-side and back-side dielectric layers 214, 216 may be formed of multiple layers of two or more materials.

The front side dielectric layer 214 may be formed over the plate and IDTs of some (e.g., selected ones) of the XBAR devices in a filter. The front side dielectric 214 may be formed between and cover the plate and IDT finger of some XBAR devices but not be formed on other XBAR devices. For example, a front side frequency-setting and/or coupling setting dielectric layer may be formed over the plate and IDTs of shunt resonators to lower the resonance frequencies of the shunt resonators with respect to the resonance frequencies of series resonators, which have thinner or no front side dielectric. Some filters may include two or more different thicknesses of front side dielectric over various resonators. The resonance frequency of the resonators can be set thus frequency “tuning” the resonator, at least in part, by selecting a thicknesses of the front side dielectric to create a certain resonant and/or anti-resonant frequency. The resonator coupling can also be set thus coupling “tuning” the resonator, at least in part, by selecting a thicknesses of the front side dielectric, such as a thickness that is a percentage of the thickness of the plate, to maximize an increase in the coupling.

The plate 110 and fingers 136/236 are dielectric coated with layer 214 having a thickness as compared to the plate, for coupling optimization to increase energy coupling between the IDT fingers and the piezoelectric plate for wider resonator bandwidth. The coupling optimization increases the frequency separation between resonance and anti-resonance for the resonator. This is directly proportional to the “electromechanical coupling”, which is the ratio of mechanical energy (e.g., energy put into the resonator A1 mode for an A1 mode resonator) versus electrical input energy. In this sense, the coupling optimization increases how well the input electrical energy “couples” into the mechanical A1 XBAR mode trying to be excited. The thickness of layer 214 may be selected as compared to the thickness of the plate 110 so that coupling increases to a maximum, thus maximizing the frequency separation between resonance and anti-resonance of the resonator.

A thickness of the dielectric layer 214 can be selected to maximize electromechanical coupling of the acoustic resonator by causing a maximum peak in coupling at a selected or predetermined thickness tfd of the dielectric layer 214. The thickness of the dielectric layer 214 may be selected based on the thickness of the plate. A thickness of the dielectric layer 214 as compared to the thickness of the plate may optimize or maximize electromechanical coupling of the acoustic resonator.

The coupling may be increased by providing a frontside dielectric coating 214 of appropriate thickness tfd over the top or front surface 112 of the piezoelectric plate and of the IDT or fingers. By tuning the front side dielectric coating thickness, the coupling can be maximized when the ratio of dielectric coating thickness to piezoelectric plate thickness is approximately or equal to 20%.

The tfd may be between 1 and 45 percent the thickness of the plate ts. The tfd may be between 10 and 30 percent the thickness of the plate ts. The tfd may be between 15 and 25 percent the thickness of the plate ts. It may be between 18 and 22 percent the thickness of the plate ts. The tfd may be 20 percent the thickness of the plate ts.

In some cases, the dielectric layer 214 is SiO2 and the thickness tfd of the dielectric layer is between 10 to 30 percent a thickness of the plate ts. In this case, the coupling increases for between 1 and about 35 percent of tfd to ts. In this case, the thickness of the dielectric layer may be 20 percent the thickness of the plate, and optimizing the electromechanical coupling includes a 10 percent increase in coupling between the portion of the piezoelectric plate that spans the cavity (e.g., the membrane and/or diaphragm) and the fingers.

In some cases, the dielectric layer 214 is Si3N4 and the thickness tfd of the dielectric layer is between 10 to 35 percent a thickness of the plate ts. In this case, the coupling increases for between 1 and about 45 percent of tfd to ts. In this case, the thickness of the dielectric layer may be 20 percent the thickness of the plate, and optimizing the electromechanical coupling includes a 10 percent increase in coupling between the portion of the piezoelectric plate that spans the cavity (e.g., the membrane and/or diaphragm) and the fingers.

Further, a passivation layer may be formed over the entire surface of the XBAR device 100 except for contact pads where electric connections are made to circuity external to the XBAR device. The passivation layer is a thin dielectric layer intended to seal and protect the surfaces of the XBAR device while the XBAR device is incorporated into a package. The front side dielectric layer and/or the passivation layer may be, SiO₂, Si₃N₄, Al₂O₃, some other dielectric material, or a combination of these materials.

The thickness of the passivation layer may be selected to protect the piezoelectric plate and the metal conductors from water and chemical corrosion, particularly for power durability purposes. It may range from 10 to 100 nm. The passivation material may consist of multiple oxide and/or nitride coatings such as SiO2 and Si3N4 material.

The IDT fingers 236 may be one or more layers of aluminum or a substantially aluminum alloy, copper or a substantially copper alloy, beryllium, tungsten, molybdenum, gold, or some other conductive material. Thin (relative to the total thickness of the conductors) layers of other metals, such as chromium or titanium, may be formed under and/or over the fingers to improve adhesion between the fingers and the piezoelectric plate 110 and/or to passivate or encapsulate the fingers. The busbars (132, 134 in FIG. 1) of the IDT may be made of the same or different materials as the fingers.

Dimension p is the center-to-center spacing or “pitch” of the IDT fingers, which may be referred to as the pitch of the IDT and/or the pitch of the XBAR. Dimension w is the width or “mark” of the IDT fingers. The IDT of an XBAR differs substantially from the IDTs used in surface acoustic wave (SAW) resonators. In a SAW resonator, the pitch of the IDT is one-half of the acoustic wavelength at the resonance frequency. Additionally, the mark-to-pitch ratio of a SAW resonator IDT is typically close to 0.5 (i.e. the mark or finger width is about one-fourth of the acoustic wavelength at resonance). In an XBAR, the pitch p of the IDT is typically 2 to 20 times the width w of the fingers. In addition, the pitch p of the IDT is typically 2 to 20 times the thickness ts of the piezoelectric slab 212. The width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w. The thickness of the busbars (132, 134 in FIG. 1) of the IDT may be the same as, or greater than, the thickness tm of the IDT fingers.

FIG. 3A is an alternative cross-sectional view of XBAR device 300 along the section plane A-A defined in FIG. 1. In FIG. 3A, a piezoelectric plate 310 is attached to an intermediate layer 322 of a substrate 320. A portion of the piezoelectric plate 310 forms a diaphragm 315 spanning a cavity 340 in the substrate. The cavity 340, does not fully penetrate the intermediate layer 322, and is formed in the layer 322 under the portion of the piezoelectric plate 310 containing the IDT 330 of a conductor pattern (e.g., first metal or M1 layer) of an XBAR. Fingers, such as finger 336, of an IDT are disposed on the diaphragm 315. Interconnection of the IDT (e.g., busbars) 330 to signal and ground paths may be through a second conductor pattern (e.g,. M2 metal layer, not shown in FIG. 1-3A) to electrical contacts on a package.

Frontside dielectric layer 314 is formed over the plate 310 and fingers 336 at least in the area of the diaphragm 315. Plate 310, diaphragm 315, dielectric layer 314 and fingers 336 may be plate 110, diaphragm 115, dielectric layer 214 and fingers 136 (or 236). Thickness tfd of layer 314 may be that same as and selected the same as that of layer 214. The cavity 340 may be formed, for example, by etching the layer 322 before attaching the piezoelectric plate 310. Alternatively, the cavity 340 may be formed by etching the layer 322 with a selective etchant that reaches the layer 322 through one or more holes or openings 342 provided in the piezoelectric plate 310. The diaphragm 315 may be contiguous with the rest of the piezoelectric plate 310 around a large portion of a perimeter 345 of the cavity 340. For example, the diaphragm 315 may be contiguous with the rest of the piezoelectric plate 310 around at least 50% of the perimeter of the cavity 340.

Intermediate layer 322 may be one or more intermediate material layers attached between plate 310 and substrate 320. An intermediary layer may be or include a bonding layer, a BOX layer, an etch stop layer, a sealing layer, an adhesive layer or layer of other material that is attached or bonded to plate 310 and substrate 320. A layer of layers 322 may be a dielectric, an oxide, a silicon oxide, silicon nitride, an aluminum oxide, silicon dioxide or silicon nitride. Layers 322 may be one or more of any of these layers or a combination of these layers.

While the cavity 340 is shown in cross-section, it should be understood that the lateral extent of the cavity is a continuous closed band area of layer 322 that surrounds and defines the size of the cavity 340 in the direction normal to the plane of the drawing. The lateral (i.e. left-right as shown in the figure) extent of the cavity 340 is defined by the lateral edges of layer 322. The vertical (i.e., down from plate 310 as shown in the figure) extent or depth of the cavity 340 into layer 322. In this case, the cavity 340 has a side cross-section rectangular, or nearly rectangular, cross section.

The XBAR 300 shown in FIG. 3A will be referred to herein as a “front-side etch” configuration since the cavity 340 is etched from the front side of the layer 322 (before or after attaching the piezoelectric plate 310 to layer 322). The XBAR 100 of FIG. 1 will be referred to herein as a “back-side etch” configuration since the cavity 140 is etched from the back side of the substrate 120 after attaching the piezoelectric plate 110. The XBAR 300 shows one or more openings 342 in the piezoelectric plate 310 at the left and right sides of the cavity 340. However, in some cases openings 342 in the piezoelectric plate 310 are only at the left or right side of the cavity 340.

In some cases, the substrate comprises a base substrate 320 and an intermediate layer (not shown) to reinforce an intermediate bonding oxide (BOX) layer. Here, the first intermediate layer may be considered a part of the substrate base 320.

In some cases, layer 322 does not exist and the plate is bonded directly to the substrate 320; and the cavity is formed in and etched into the substrate 320.

In some cases, although not shown in the figure, layer 322 is a thinner layer than the depth of the cavity such that the plate is bonded directly to layer 322; and the cavity is formed in and etched into the layer 322 and into the substrate 320. Here, the cavity extends completely through layer 322 and has a cavity bottom in the substrate 320.

FIG. 3B is a graphical illustration of the primary acoustic mode of interest in an XBAR. FIG. 3B shows a small portion of an XBAR 350 including a piezoelectric plate 310 and three interleaved IDT fingers 336. XBAR 350 may be part of any XBAR herein. An RF voltage is applied to the interleaved fingers 336. This voltage creates a time-varying electric field between the fingers. The direction of the electric field is primarily lateral, or parallel to the surface of the piezoelectric plate 310, as indicated by the arrows labeled “electric field”. Due to the high dielectric constant of the piezoelectric plate, the electric field is highly concentrated in the plate relative to the air. The lateral electric field introduces shear deformation, and thus strongly excites a primary shear-mode acoustic mode, in the piezoelectric plate 310. In this context, “shear deformation” is defined as deformation in which parallel planes in a material remain parallel and maintain a constant distance while translating relative to each other. A “shear acoustic mode” is defined as an acoustic vibration mode in a medium that results in shear deformation of the medium. The shear deformations in the XBAR 350 are represented by the curves 360, with the adjacent small arrows providing a schematic indication of the direction and magnitude of atomic motion. The degree of atomic motion, as well as the thickness of the piezoelectric plate 310, have been greatly exaggerated for ease of visualization. While the atomic motions are predominantly lateral (i.e. horizontal as shown in FIG. 3B), the direction of acoustic energy flow of the excited primary shear acoustic mode is substantially orthogonal to the front and back surface of the piezoelectric plate, as indicated by the arrow 365.

An acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. The piezoelectric coupling for shear wave XBAR resonances can be high (>20%) compared to other acoustic resonators. High piezoelectric coupling enables the design and implementation of microwave and millimeter-wave filters with appreciable bandwidth.

A definition of resonator coupling used in this document may be:

$${k}^{2} = \left(f {a}^{2} - f {r}^{2}\right) / \left(f {a}^{2}\right)$$

Where k² = is the coupling, ƒ α is the anti-resonant frequency and fr is the resonant frequency of the XBAR for the graph. In some cases, k² goes down for small pitches.

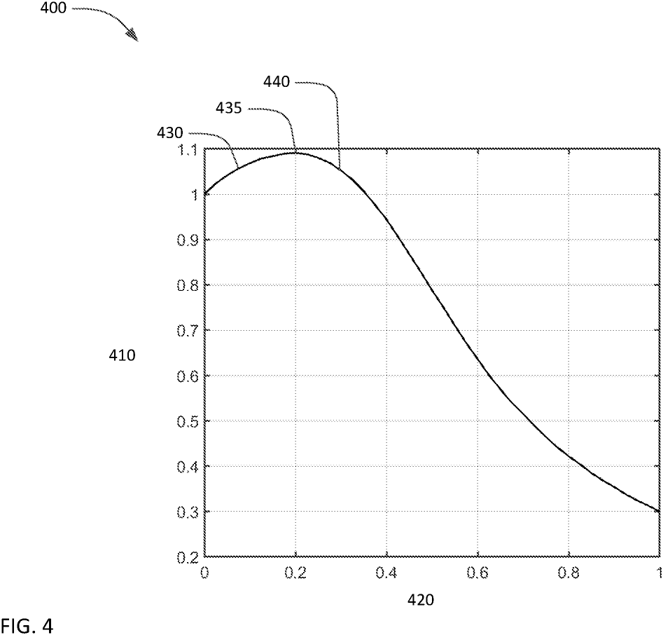

FIG. 4 shows a graph 400 of the coupling 410 of an XBAR as a function of frontside oxide thickness/plate thickness (e.g., tfd/ts) 420. Graph 400 may be for a version of an XBAR of any of FIGS. 1 to 3. Graph 400 may be the results of a finite element method (FEM) simulation performed for an XBAR having the plate 110/310 with a thickness ts of 400 nm of Z-cut LiNbO3; the frontside dielectric is thickness tfd of SiO2; the fingers are 10 nm thick metal electrodes with a 20 nm mark; and the fingers have a pitch p = 4 um/scalefactor, where scalefactor = 400 nm(ts) / TotalThickness(tfd+ts). Thickness tfd is variable and the diaphragm Totalthickness (e.g., tfd + ts) is tfd + 400 nm, so scalefactor = 400 nm/ Totalthickness. Here, for example, scalefactor is between 1/1.1 and 1/1.3 (or can be 1/1.2) = between 0.91 - 0.77 (or can be 0.833); so pitch = is between 4.4 - 5.2 (or can be 4.8 um). Pitch p may = ts / (ts/(ts + tfd)). For example, pitch p may be 4.8 um when ts is 400 nm and tfd is 20% of ts, or 80 nm.

Here the pitch may be scaled along with the total thickness to avoid spurious modes impacting the result. This also removes any impact of the pitch on the coupling, which is known to fundamentally exist. Here, the dielectric constant of the SiO2 fsd may be ∈ = 4.5∈0.

Graph 400 shows that there is a clearly pronounced maximum in coupling as thickness tfd is increased from zero to about 20 percent thickness tfd/ts. The maximum coupling 435 is at approximately 20 percent oxide thickness tfd/ts. The maximum coupling 435 provides approximately 10 percent increase in coupling. Above this value, coupling drops sharply. Increases of about 5 percent of coupling are shown at 430 and 440 which are approximately 5 percent and 30 percent oxide thickness tfd/ts. There is an increase in coupling from about 1 to about 35 percent of tfd/ts.

In some cases, the dielectric layer 214 is Si3N4 and the thickness tfd of the dielectric layer is between 10 to 35 percent a thickness of the plate ts. In this case, the coupling increases for between 1 and about 45 percent of tfd to ts. In this case, the thickness of the dielectric layer may be 20 percent the thickness of the plate, and optimizing the electromechanical coupling includes a 10 percent increase in coupling between the portion of the piezoelectric plate that spans the cavity (e.g., the membrane and/or diaphragm) and the fingers.

A pitch p of the fingers may be between 3 and 7 um. It may be between 4 and 6 um. It may be 4.8 um. Pitch p may = ts / (ts/(ts + tfd)). For example, pitch p may be 4.8 um when ts is 400 nm and tfd is 20% of ts.

In some cases, the plate has a thickness ts of 400 nm and is one of Z-cut or 128-Y Cut LiNbO3; the fingers are 10 nm thick metal electrodes with a 20 nm mark; the fingers have a pitch p of between 4.4 and 5.2 um; and tfd is between 15 and 25 percent ts. Here, pitch may = 4 um/scalefactor, where scalefactor = 400 nm(ts) / TotalThickness(tfd+ts). For example, scalefactor is between 1/1.1 and 1/1.3 (or can be 1/1.2) = between 0.91 - 0.77 (or can be 0.833); so pitch = is between 4.4 - 5.2 (or can be 4.8 um).

For example, the dielectric layer 214 may be is SiO2 and the thickness tfd of the dielectric layer is between 10 to 30 percent a thickness of the plate ts. In this case, the coupling increases for between 1 and about 35 percent of tfd to ts. In this case, the thickness of the dielectric layer may be 20 percent the thickness of the plate, and optimizing the electromechanical coupling includes a 10 percent increase in coupling between the portion of the piezoelectric plate that spans the cavity (e.g., the membrane and/or diaphragm) and the fingers.

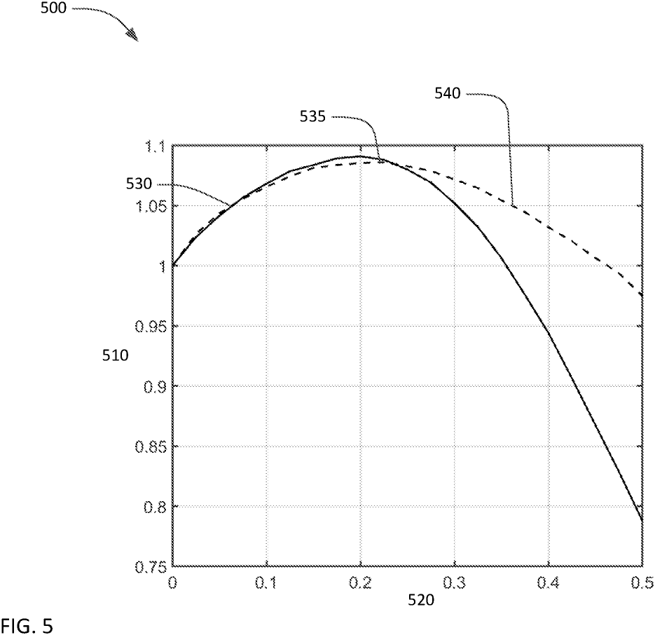

FIG. 5 shows a graph 500 of the coupling 510 of two XBARs as a function of each of their frontside oxide thickness/plate thickness (e.g., tfd/ts) 520. Graph 500 may be for two versions of an XBAR of any of FIGS. 1 to 3. Graph 500 may be the results of a FEM simulation performed for the XBAR of graph 400 shown as the solid line; and performed for an XBAR having the same features as the XBAR of graph 400, except that the frontside dielectric is thickness tfd of Si3N4 having a dielectric constant that may be ∈ = 7.0 ∈0. The pitch may be scaled as per graph 400.

Graph 500 shows that for thickness tfd of Si3N4 there is a clearly pronounced maximum in coupling as thickness tfd is increased from zero to about 20 percent thickness tfd/ts. The maximum coupling 535 is at approximately 20 or 22 percent oxide thickness tfd/ts. The maximum coupling 535 provides approximately 10 percent increase in coupling. Above this value, coupling drops more slowly than for the SiO2 dielectric. Increases of about 5 percent of coupling are shown at 530 and 540 which are approximately 5 percent and 35 percent oxide thickness tfd/ts. There is an increase in coupling from about 1 to about 45 percent of tfd/ts. For XBARS of graph 500, other effects lead to an extreme drop off of coupling for thick dielectric values of frontside dielectric.

Graphs 400 and 500 shown that the existence of a k² coupling maxima at nonzero tfd of the oxide may be due to the fact that total coupling of the XBAR depends on the dielectric coefficient of the frontside dielectric as well as the piezoelectric coefficients of the plate. The k² coupling may be inversely proportional to the dielectric coefficient of the frontside dielectric. In some cases, since the plate (e.g., LN) dielectric constant (approximately or at 45) is much greater than the dielectric constant for a frontside dielectric of SiO2 (approximately or at 4), as SiO2 is added the effective dielectric constant drops. This drop in dielectric constant from adding SiO2 fsd allows k² coupling to rise at moderate SiO2 thicknesses, such as between 1 and 40 percent thickness of the plate. As SiO2 is increased further, the piezoelectricity portion dominates and k² coupling drops rapidly.

This effect of adding the frontside dielectric, such as of SiO2 or Si3N4, is universally observed in both Z-cut LN and 128-Y cut LN plates with identical shape. The existence of a maximum approximately or at 20 percent thickness tfd/ts is independent of the detailed IDT parameters (pitch, mark, metal thickness, sidewall angle, etc.). The detailed IDT parameters may, however, impact the strength of the effect. For example, for a “high power XBAR” with 500 nm thick Al fingers and mark of 1 um, the k² coupling t rises only 5% above its nominal value at no oxide.

It is conceived that other frontside dielectric materials will produce a similar effect in proportion to their dielectric difference from the piezoelectric substrate. The precise dielectric realization or material of the frontside dielectric may shift the optimum from 20 percent thickness tfd/ts. This shift may be to 10, 15, 25 or 30 percent thickness tfd/ts.

### Description of Methods

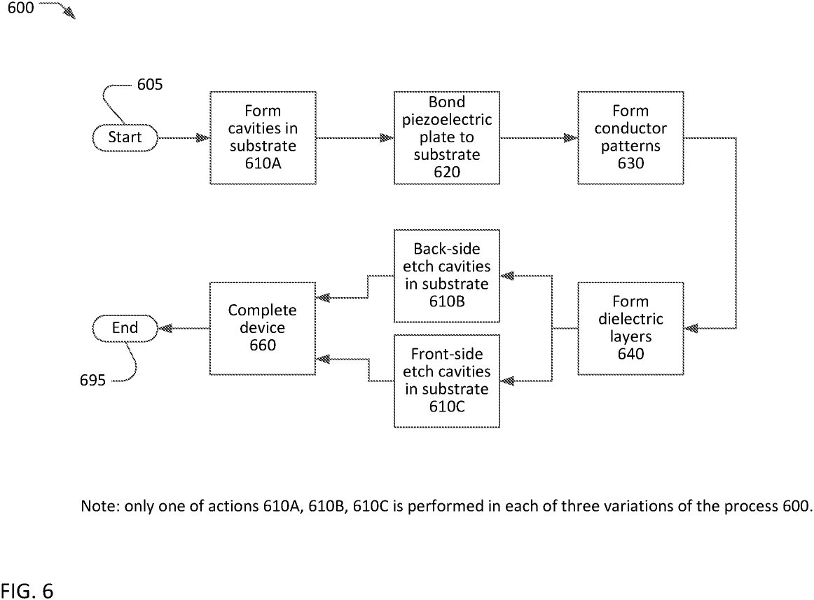

FIG. 6 is a simplified flow chart showing a process 600 for making an XBAR or a filter incorporating XBARs. The process 600 may form XBAR 400 or an example of that XBAR. The process 600 starts at 605 with a substrate and a plate of piezoelectric material and ends at 695 with a completed XBAR or filter. As will be described subsequently, the piezoelectric plate may be mounted on a sacrificial substrate or may be a portion of wafer of piezoelectric material. The flow chart of FIG. 6 includes only major process steps. Various conventional process steps (e.g. surface preparation, chemical mechanical processing (CMP), cleaning, inspection, deposition, photolithography, baking, annealing, monitoring, testing, etc.) may be performed before, between, after, and during the steps shown in FIG. 6.

The flow chart of FIG. 6 captures three variations of the process 600 for making an XBAR which differ in when and how cavities are formed in the substrate. The cavities may be formed at steps 610A, 610B, or 610C. Only one of these steps is performed in each of the three variations of the process 600.

The piezoelectric plate may be, for example, Z-cut, rotated Z-cut, or rotated Y-cut lithium niobate or lithium tantalate. In some cases, it is Y-cut or rotated Y-cut lithium niobate. The piezoelectric plate may be some other material and/or some other cut. The substrate may be silicon. The substrate may be some other material that allows formation of deep cavities by etching or other processing. The silicon substrate may have layers of silicon TOX and polycrystalline silicon.

In one variation of the process 600, one or more cavities are formed in the substrate 120 or 320 at 610A, before the piezoelectric plate is bonded to the substrate at 620. A separate cavity may be formed for each resonator in a filter device. The one or more cavities may be formed using conventional photolithographic and etching techniques. These techniques may be isotropic or anisotropic; and may use deep reactive ion etching (DRIE). Typically, the cavities formed at 610A will not penetrate through the substrate or layer 322, and the resulting resonator devices will have a cross-section as shown in FIG. 3A.

At 620, the piezoelectric plate is bonded to the substrate. The piezoelectric plate and the substrate may be bonded by a wafer bonding process. Typically, the mating surfaces of the substrate and the piezoelectric plate are highly polished. One or more layers of intermediate materials, such as an oxide or metal, may be formed or deposited on the mating surface of one or both of the piezoelectric plate and the substrate. One or both mating surfaces may be activated using, for example, a plasma process. The mating surfaces may then be pressed together with considerable force to establish molecular bonds between the piezoelectric plate and the substrate or intermediate material layers.

In a first variation of 620, the piezoelectric plate is initially mounted on a sacrificial substrate. After the piezoelectric plate and the substrate are bonded, the sacrificial substrate, and any intervening layers, are removed to expose the surface of the piezoelectric plate (the surface that previously faced the sacrificial substrate).The sacrificial substrate may be removed, for example, by material-dependent wet or dry etching or some other process.

In a second variation of 620 starts with a single-crystal piezoelectric wafer. Ions are implanted to a controlled depth beneath a surface of the piezoelectric wafer (not shown in FIG. 6). The portion of the wafer from the surface to the depth of the ion implantation is (or will become) the thin piezoelectric plate and the balance of the wafer is effectively the sacrificial substrate. After the implanted surface of the piezoelectric wafer and device substrate are bonded, the piezoelectric wafer may be split at the plane of the implanted ions (for example, using thermal shock), leaving a thin plate of piezoelectric material exposed and bonded to the substrate. The thickness of the thin plate piezoelectric material is determined by the energy (and thus depth) of the implanted ions. The process of ion implantation and subsequent separation of a thin plate is commonly referred to as “ion slicing”. The exposed surface of the thin piezoelectric plate may be polished or planarized after the piezoelectric wafer is split.

Conductor patterns and dielectric layers defining one or more XBAR devices are formed on the surface of the piezoelectric plate at 630. Typically, a filter device will have two or more conductor layers that are sequentially deposited and patterned. The conductor layers may include bonding pads, gold or solder bumps, or other means for making connection between the device and external circuitry. The conductor layers may be, for example, aluminum, an aluminum alloy, copper, a copper alloy, molybdenum, tungsten, beryllium, gold, or some other conductive metal. Optionally, one or more layers of other materials may be disposed below (i.e. between the conductor layer and the piezoelectric plate) and/or on top of the conductor layer. For example, a thin film of titanium, chrome, or other metal may be used to improve the adhesion between the conductor layers and the piezoelectric plate. The conductor layers may include bonding pads, gold or solder bumps, or other means for making connection between the device and external circuitry.

Conductor patterns may be formed at 630 by depositing the conductor layers over the surface of the piezoelectric plate and removing excess metal by etching through patterned photoresist. Alternatively, the conductor patterns may be formed at 630 using a lift-off process. Photoresist may be deposited over the piezoelectric plate and patterned to define the conductor pattern. The conductor layer may be deposited in sequence over the surface of the piezoelectric plate. The photoresist may then be removed, which removes the excess material, leaving the conductor pattern. In some cases, forming at 630 occurs prior to bonding at 620, such as where the IDT’s are formed prior to bonding the plate to the substrate.

Forming conductor patterns at 630 may include forming the IDT 430 having busbars that terminate in beveled corners 438 and 439 that extend off of the diaphragm as straight line side edges 443 of the busbars that form angles An1 with a perimeter edge 440 of the cavity 140 at junctions J1 and thus reduce stress and deformation of the diaphragm at junctions J1, such as shown in and described for FIG. 4 or described for an example of that XBAR.

At 640, a front-side dielectric layer or layers may be formed by depositing one or more layers of dielectric material on the front side of the piezoelectric plate, over one or more desired conductor patterns of IDT or XBAR devices. The one or more dielectric layers may be deposited using a conventional deposition technique such as sputtering, evaporation, or chemical vapor deposition. The one or more dielectric layers may be deposited over the entire surface of the piezoelectric plate, including on top of the conductor pattern. Alternatively, one or more lithography processes (using photomasks) may be used to limit the deposition of the dielectric layers to selected areas of the piezoelectric plate, such as only between the interleaved fingers of the IDTs. Masks may also be used to allow deposition of different thicknesses of dielectric materials on different portions of the piezoelectric plate. In some cases, depositing at 640 includes depositing a first thickness of at least one dielectric layer over the front-side surface of selected IDTs, but no dielectric or a second thickness less than the first thickness of at least one dielectric over the other IDTs. An alternative is where these dielectric layers are only between the interleaved fingers of the IDTs.

The one or more dielectric layers may include, for example, a dielectric layer selectively formed over the IDTs of shunt resonators to shift the resonance frequency of the shunt resonators relative to the resonance frequency of series resonators as described in U.S. Pat. No. 10,491,192. The one or more dielectric layers may include an encapsulation/passivation layer deposited over all or a substantial portion of the device.

The different thickness of these dielectric layers causes the selected XBARs to be tuned to different frequencies as compared to the other XBARs. For example, the resonance frequencies of the XBARs in a filter may be tuned using different front-side dielectric layer thickness on some XBARs.

As compared to the admittance of an XBAR with tfd = 0 (i.e. an XBAR without dielectric layers), the admittance of an XBAR with tfd = 30 nm dielectric layer reduces the resonant frequency by about 145 MHz compared to the XBAR without dielectric layers. The admittance of an XBAR with tfd = 60 nm dielectric layer reduces the resonant frequency by about 305 MHz compared to the XBAR without dielectric layers. The admittance of an XBAR with tfd = 90 nm dielectric layer reduces the resonant frequency by about 475 MHz compared to the XBAR without dielectric layers. Importantly, the presence of the dielectric layers of various thicknesses has little or no effect on the piezoelectric coupling.

At 640, the resonator coupling can also be set thus coupling “tuning” the resonator, at least in part, by selecting a thicknesses tfd of the front side dielectric (e.g., layer 214 or 314), such as a thickness that is a percentage of the thickness of the plate, to maximize an increase in the coupling. Here, the plate 110 and fingers 136/236 are dielectric coated with layer 214 having a thickness as compared to the plate, for coupling optimization to increase energy coupling between the IDT fingers and the piezoelectric plate for wider resonator bandwidth. The thickness of layer 214 may be selected as compared to the thickness of the plate so that coupling optimization increases to a maximum, thus maximizing the frequency separation between resonance and anti-resonance for the resonator.

A thickness of the dielectric layer 214 can be selected to optimize electromechanical coupling of the acoustic resonator by causing a maximum peak in coupling at a selected or predetermined thickness tfd of the dielectric layer 214. The coupling may be increased by providing a frontside dielectric coating 214 of appropriate thickness tfd over the top or front surface 112 of the piezoelectric plate and of the IDT or fingers. By tuning the front side dielectric coating thickness, the coupling can be maximized when the ratio of dielectric coating thickness to piezoelectric plate thickness is approximately or at 20%.

In a second variation of the process 600, one or more cavities are formed in the back side of the substrate at 610B after all the conductor patterns and dielectric layers are formed at 630. A separate cavity may be formed for each resonator in a filter device. The one or more cavities may be formed using an anisotropic or orientation-dependent dry or wet etch to open holes through the back-side of the substrate to the piezoelectric plate. In this case, the resulting resonator devices will have a cross-section as shown in FIG. 1.

In a third variation of the process 600, one or more cavities in the form of recesses in the substrate top layer 322 may be formed at 610C by etching a sacrificial layer formed in the front side of the substrate using an etchant introduced through openings in the piezoelectric plate. A separate cavity may be formed for each resonator in a filter device. The one or more cavities may be formed using an isotropic or orientation-independent dry etch that passes through holes in the piezoelectric plate and etches the sacrificial layer formed in recesses in the front-side of the substrate. The one or more cavities formed at 610C will not penetrate completely through the substrate top layer 322, and the resulting resonator devices will have a cross-section as shown in FIG. 3A.

In all variations of the process 600, the filter or XBAR device is completed at 660. Actions that may occur at 660 include depositing an encapsulation/passivation layer such as SiO₂ or Si₃O₄ over all or a portion of the device; forming bonding pads or solder bumps or other means for making connection between the device and external circuitry; excising individual devices from a wafer containing multiple devices; other packaging steps; and testing. Another action that may occur at 660 is to tune the resonant frequencies of the resonators within a filter device by adding or removing metal or dielectric material from the front side of the device. After the filter device is completed, the process ends at 695. FIGS. 1-4 may show examples of the fingers of selected IDTs after completion at 660.

Forming the cavities at 610A may require the fewest total process steps but has the disadvantage that the XBAR diaphragms will be unsupported during all of the subsequent process steps. This may lead to damage to, or unacceptable distortion of, the diaphragms during subsequent processing.

Forming the cavities using a back-side etch at 610B requires additional handling inherent in two-sided wafer processing. Forming the cavities from the back side also greatly complicates packaging the XBAR devices since both the front side and the back side of the device must be sealed by the package.

Forming the cavities by etching from the front side at 610C does not require two-sided wafer processing and has the advantage that the XBAR diaphragms are supported during all of the preceding process steps. However, an etching process capable of forming the cavities through openings in the piezoelectric plate will necessarily be isotropic. However, as illustrated in FIG. 3A, such an etching process using a sacrificial material allows for a controlled etching of the cavity, both laterally (i.e. parallel to the surface of the substrate) as well as normal to the surface of the substrate.

Although the description herein relate to an XBAR filter, the same concepts can be applied to a surface acoustic wave resonator (SAW), a bulk acoustic wave (BAW) resonator, a film bulk acoustic wave (FBAW) resonator, a temperature compensated surface acoustic wave resonator (TC-SAW), or a solidly-mounted transversely-excited film bulk acoustic resonator (SM-XBAR). They could also be any of a number of combinations of these types of resonators.

### Closing Comments

Throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

It is claimed:

1. An acoustic resonator comprising:
a piezoelectric plate, a portion of the piezoelectric plate spanning a cavity in an intermediate layer of a substrate;
an interdigital transducer on a surface of the piezoelectric plate, interleaved fingers of the IDT on the portion of the piezoelectric plate that spans the cavity; and
a dielectric layer over the interleaved fingers and the surface of the portion of the piezoelectric plate that spans the cavity,
wherein a thickness of the dielectric layer optimizes electromechanical coupling of the acoustic resonator.

2. The device of claim 1, wherein
the dielectric layer is one of SiO2 and Si3N4; and
the thickness of the dielectric layer is between 10 to 30 percent of a thickness of the plate.

3. The device of claim 2, wherein a pitch of the fingers is 4 um / (400 nm/(400 nm + a thickness of the dielectric layer)).

4. The device of claim 1, wherein:
the dielectric layer is SiO2;
the thickness of the dielectric layer is between 10 to 30 percent a thickness of the plate.

5. The device of claim 4, wherein the thickness of the dielectric layer is 20 percent the thickness of the plate, and wherein optimizing the electromechanical coupling includes a 10 percent increase in resonator coupling as compared to a similar resonator without the dielectric layer.

6. The device of claim 1, wherein:
the dielectric layer is Si3N4;
a thickness of the dielectric layer is between 10 to 35 percent a thickness of the plate.

7. The device of claim 6, wherein the thickness of the dielectric layer is 20 percent the thickness of the plate, and wherein optimizing the electromechanical coupling includes a 10 percent increase in resonator coupling as compared to a similar resonator without the dielectric layer.

8. The device of claim 1, wherein:
the plate has a thickness of 400 nm and is one of Z-cut or 128-Y Cut LiNbO3;
the fingers are 10 nm thick metal electrodes with a 20 nm mark; and
the fingers have a pitch of between 4.4 and 5.2 um.

9. An acoustic resonator device comprising:
a single-crystal piezoelectric plate having parallel front and back surfaces, the back surface attached to the surface of an intermediate layer of a substrate except for a portion of the piezoelectric plate forming a diaphragm that spans a cavity formed in the intermediate layer of the substrate;
an interdigital transducer (IDT) formed on the front surface of the single-crystal piezoelectric plate such that interleaved fingers of the IDT are disposed on the diaphragm, the single-crystal piezoelectric plate and the IDT configured such that a radio frequency signal applied to the IDT excites a shear primary acoustic mode within the diaphragm;
a dielectric layer over the interleaved fingers and the surface of the portion of the piezoelectric plate that spans the cavity,
wherein a thickness of the dielectric layer maximizes electromechanical coupling of the acoustic resonator.

10. The device of claim 9, wherein
the plate has a thickness of 400 nm;
the dielectric layer is one of SiO2 and Si3N4;
the thickness of the dielectric layer is between 10 to 30 percent a thickness of the plate; and
a pitch of the fingers is between 5 and 6 um.

11. The device of claim 9, wherein:
the dielectric layer is SiO2;
the thickness of the dielectric layer is between 10 to 30 percent a thickness of the plate.

12. The device of claim 11, wherein the thickness of the dielectric layer is 20 percent the thickness of the plate, and wherein optimizing the electromechanical coupling includes a 10 percent increase in resonator coupling as compared to a similar resonator without the dielectric layer.

13. The device of claim 9, wherein:
the dielectric layer is Si3N4;
a thickness of the dielectric layer is between 10 to 35 percent a thickness of the plate.

14. The device of claim 13, wherein the thickness of the dielectric layer is 20 percent the thickness of the plate, and wherein optimizing the electromechanical coupling includes a 10 percent increase in resonator coupling as compared to a similar resonator without the dielectric layer.

15. The device of claim 9, wherein:
the plate has a thickness of 400 nm and is one of Z-cut or 128-Y Cut LiNbO3;
the fingers are 10 nm thick metal electrodes with a 20 nm mark; and
the fingers have a pitch of between 4.4 and 5.2 um.

16. A method of fabricating an acoustic resonator device having a dielectric layer selected to optimize electromechanical coupling, the method comprising:
attaching a back surface of a single crystal piezoelectric plate to a surface of an intermediate layer of a substrate;
forming a cavity in the intermediate layer of the substrate such that a portion of the single-crystal piezoelectric plate forms a diaphragm spanning the cavity; and
forming an interdigital transducer (IDT) on the front surface of the single-crystal piezoelectric plate such that interleaved fingers of the IDT are disposed on the diaphragm, the single-crystal piezoelectric plate and the IDT configured such that a radio frequency signal applied to the IDT excites a shear primary acoustic mode within the diaphragm;
forming a dielectric layer over the interleaved fingers and the surface of the portion of the piezoelectric plate that spans the cavity,
wherein a thickness of the dielectric layer is selected to optimize electromechanical coupling of the acoustic resonator.

17. The method of claim 16, further comprising selecting the thickness of the dielectric layer based on a thickness of the plate.

18. The method of claim 17, wherein selecting is selecting the thickness of the dielectric layer to be between 10 and 30 percent the thickness of the plate.

19. The method of claim 16, wherein
the plate has a thickness of 400 nm;
the dielectric layer is one of SiO2 and Si3N4;
the thickness of the dielectric layer is between 10 to 30 percent a thickness of the plate; and
a pitch of the fingers is between 5 and 6 um.
